(19) United States
(12) Patent Application Publication
(10) Pub. No.: US 2013/0015870 A1
(43) Pub. Date: Jan. 17, 2013

(54) TEST SYSTEM WITH CONTACT TEST PROBES

(71) Applicants: Joshua G. Nickel, San Jose, CA (US); Mattia Pascolini, San Mateo, CA (US); Adil Syed, Santa Clara, CA (US)

(72) Inventors: Joshua G. Nickel, San Jose, CA (US); Mattia Pascolini, San Mateo, CA (US); Adil Syed, Santa Clara, CA (US)

(21) Appl. No.: 13/183,393

(22) Filed: Jul. 14, 2011

(51) Int. Cl. G01R 31/20

(52) U.S. Cl. 324/754.03

(57) ABSTRACT

Electronic device structures such as structures containing antennas, cables, connectors, welds, electronic device components, conductive housing structures, and other structures can be tested for faults using a test system to perform conducted testing. The test system may include a vector network analyzer or other test unit that generates radio-frequency test signals in a range of frequencies. The radio-frequency test signals may be transmitted to electronic device structures under test using a contact test probe that has at least signal and ground pins. The test probe may receive corresponding radio-frequency signals. The transmitted and received radio-frequency test signals may be analyzed to determine whether the electronic device structures under test contain a fault.

### BACKGROUND

This relates to testing and, more particularly, to testing of electronic device structures.

Electronic devices such as computers, cellular telephones, music players, and other electronic equipment are often provided with wireless communications circuitry. In a typical configuration, the wireless communications circuitry includes an antenna that is coupled to a transceiver on a printed circuit board using radio-frequency cables and connectors. Many electronic devices include conductive structures with holes, slots, and other shapes. Welds and springs may be used in forming connections between such types of conductive structures and electronic device components.

During device assembly, workers and automated assembly machines may be used to form welds, machine features into conductive device structures, connect connectors for antennas and other components to mating connectors, and otherwise form and interconnect electronic device structures. If care is not taken, however, faults may result that can impact the performance of a final assembled device. For example, a metal part may not be machined correctly or a connector may not be seated properly within its mating connector. In some situations, it can be difficult or impossible to detect and identify these faults, if at all, until assembly is complete and a finished device is available for testing. Detection of faults only after assembly is complete can results in costly device scrapping or extensive reworking.

It would therefore be desirable to be able to provide improved ways in which to detect faults during the manufacturing of electronic devices.

### SUMMARY

A test system may be provided for performing tests on electronic device structures. The electronic device structures may be tested during manufacturing, before or after the structures are fully assembled to form a finished electronic device. Testing may reveal faults that might otherwise be missed in tests on finished devices and may detect faults at a sufficiently early stage in the manufacturing process to allow parts to be reworked or scrapped at minimal.

The electronic device structures may contain structures such as antennas, connectors and other conductive structures that form electrical connections, cables connected to the connectors, welds, solder joints, conductive traces, conductive surfaces on conductive housing structures and other device structures, dielectric layers such as foam layers, electronic components, and other structures. These structures can be tested using radio-frequency test signals generated using the test system. During testing, the device structures under test may be placed in a test fixture.

The test system may include a vector network analyzer or other test unit that generates radio-frequency tests signals in a range of frequencies. The radio-frequency test signals may be transmitted to electronic device structures under test using a contact (or wired) test probe. The contact test probe may include at least signal and ground pins for making physical contact at desired locations on the device structures under test.

During testing, one or more contact test probe may be used to probe corresponding structures to be tested such as electronic device antennas, connectors, structures with welds, electronic components, conductive housing structures, conductive traces, conductive surfaces on housing structures or other device structures, device structures including dielectric layers, structures with solder joints, and other structures to perform conducted testing. The test probe may receive corresponding radio-frequency signals from the device structures under test. For example, the test probe may receive reflected radio-frequency signals or radio-frequency signals that have been transmitted through the device structures under test. The transmitted and reflected radio-frequency test signals may be analyzed to produce complex impedance measurements and complex forward transfer coefficient measurements (when two or more test probes are used). These measurements or other gathered test data may be compared to previously obtained baseline measurements on properly assembled structures to determine whether the electronic device structures under test contain a fault.

Further features of the present invention, its nature and various advantages will be more apparent from the accompanying drawings and the following detailed description.

### BRIEF DESCRIPTION OF THE DRAWINGS

FIG. 1 is a diagram of an illustrative test system environment in which electronic device structures may be tested using a test probe configured to make physical contact with at least a portion of the electronic device structures in accordance an embodiment of the present invention.

FIG. 2 is a diagram showing a test probe that may be used to test for proper connection of a radio-frequency cable in accordance an embodiment of the present invention.

FIG. 3 is a graph showing how the magnitude of reflected radio-frequency signals that are received by a test probe may vary as a function of whether a test structure contains faults in accordance with an embodiment of the present invention.

FIG. 4 is a graph showing how the phase of reflected radio-frequency signals that are received by a test probe may vary as a function of whether a test structure contains faults in accordance with an embodiment of the present invention.

FIGS. 5A, 5B, and 5C are diagrams of exemplary test probes configured to make direct contact with electronic device structures during testing in accordance with an embodiment of the present invention.

FIG. 6 is a perspective view of illustrative electronic device structures attached via a coupling mechanism that may be tested using a test probe in accordance with an embodiment of the present invention.

FIG. 7 is a top view of illustrative electronic device structures that include a conductive planar electronic device housing structure having slots that may be tested using a test probe in accordance with an embodiment of the present invention.

FIG. 8 is a top view of illustrative electronic device structures that include conductive structures with welds that may be tested using a test probe in accordance with an embodiment of the present invention.

FIG. 9 is a side view of illustrative electronic device structures attached via a screw that may be tested using a test probe in accordance with an embodiment of the present invention.

FIG. 10 is a side view of an illustrative electronic component in an electronic device that has electrical contacts that are configured to make contact with mating contacts on a printed circuit board in the electronic device in accordance with an embodiment of the present invention.

FIG. 11 is a side view of an illustrative electronic component mounted to a substrate using solder of the type that may be tested using a test probe in accordance with an embodiment of the present invention.

FIG. 12 is a side view of an illustrative electronic component covered with an electromagnetic shield structure of the type that may be tested using a test probe in accordance with an embodiment of the present invention.

FIG. 13 is a top view of a pair of metal traces on a substrate of the type that may be tested using a test probe in accordance with an embodiment of the present invention.

FIG. 14 is a flow chart of illustrative steps involved in performing conducted testing of electronic devices and structures in electronic devices using a contact test system of the type shown in FIG. 1 in accordance with an embodiment of the present invention.

### DETAILED DESCRIPTION

Electronic devices may be assembled from conductive structures such as conductive housing structures.

Electronic components within the structures such as speakers, microphones, displays, antennas, switches, connectors, and other components, may be mounted within the housing of an electronic device. Structures such as these may be assembled using automated manufacturing tools.

Examples of automated manufacturing tools include automated milling machines, robotic pick-and-place tools for populating printed circuit boards with connectors and integrated circuits, computer-controlled tools for attaching connectors to each other, and automated welding machines (as examples). Manual assembly techniques may also be used in assembling electronic devices. For example, assembly personnel may attach a pair of mating connectors to each other by pressing the connectors together.

Regardless of whether operations such as these are performed using automated tools or manually, there will generally be a potential for error. Parts may not be manufactured properly and faults may arise during assembly operations.

With conventional testing arrangements, these faults may sometimes be detected after final assembly operations are complete. For example, over-the-air wireless tests on a fully assembled device may reveal that an antenna is not performing within desired limits. This type of fault may be due to improper connection of a pair of connectors in the signal path between the antenna and a radio-frequency transceiver. Detection of faults at late stages in the assembly process may, however, result in the need for extensive reworking. It may often be impractical to determine the nature of the fault, forcing the device to be scrapped.

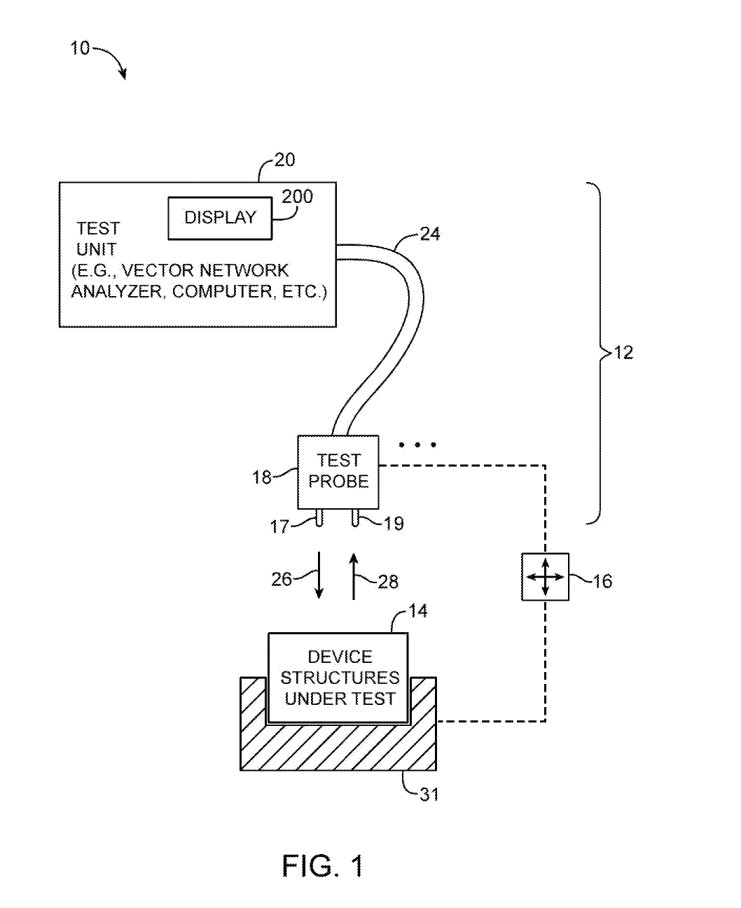

Earlier and potentially more revealing and accurate tests may be performed by using a wireless probe structure to wirelessly test electronic device structures. An illustrative test system with a wireless probe for use in testing electronic device structures is shown in FIG. 1A. In test system 10, tester 12 may be used to perform conducted (contact) tests on device structures under test 14. Device structures under test 14 may include portions of an electronic device such as conductive housing structures, electronic components such as microphones, speakers, connectors, switches, printed circuit boards, antennas, parts of antennas such as antenna resonating elements and antenna ground structures, metal parts that are coupled to each other using welds, assemblies formed from two or more of these structures, or other suitable electronic device structures. These test structures may be associated with any suitable type of electronic device such as a cellular telephone, a portable computer, a music player, a tablet computer, a desktop computer, a display, a display that includes a built-in computer, a television, a set-top box, or other electronic equipment.

Tester 12 may include a test unit such as test unit 20 and one or more test probes such as test probe 18. Test probe 18 may be used to convey radio-frequency test signals 26 to device structures 14 and to receive corresponding radio-frequency signals 28 from device structures under test 14. Signals 26 and 28 may be processed to compute complex impedance data (sometimes referred to as S11 parameter data) or other suitable data for determining whether device structures 14 contain a fault.

During testing, test probe 18 may be placed in physical contact with device structures under test 14 (e.g., to perform conducted radio-frequency testing). For example, test probe 18 may include first and second probe pins 17 and 19 configured to make contact at desired locations on device structures under test 14. Pins 17 and 19 may serve as signal and ground pins, respectively. At least one of pins 17 and 19 may be spring-loaded to reduce the chance of damaging test equipment 12 and device structures under test 14. Test probe 18 of this type may sometimes be referred to as a pogo-pin test probe. If desired, test probes such as alligator clip probes, tweezer probes, shielded-lead probes, or other types of test probes may be used in test system 10.

Device structures under test 14 may be mounted in a test fixture such as test fixture 31 during testing. Test fixture 31 may contain a cavity that receives some or all of device structures under test 14. Fixture 31 may be configured to hold device structures under test 14 via pressure and/or friction on one or more sides of structures 14. Fixture 31 may be a robotically controlled fixture having automated alignment capabilities. Test fixture 31 may, if desired, be formed from dielectric materials such as plastic to avoid interference with radio-frequency test measurements. The relative position between test probe 18 and device structures under test 14 may be controlled manually by an operator of test system 10 or may be adjusted using computer-controlled or manually controlled positioner such as positioner 16. Positioner 16 may include actuators for controlling horizontal and/or vertical movement of test probe 18 and/or device structures under test 14.

Test unit 20 may include signal generator equipment that generates radio-frequency test signals over a range of frequencies. These generated test signals may be provided to test probe 18 over radio-frequency cable 24 (e.g., a coaxial cable). Radio-frequency cable 24 may include an inner conductor that is coupled to signal pin 17 and an outer tubular conductor that is coupled to ground pin 19. The inner and outer conductors of cable 24 may be electrically isolated with dielectric material. In scenarios in which more than one test probe 18 is used to test device structures under test 14, multiple radio-frequency cables may be used to couple a respective one of the test probes to test unit 20.

Test unit 20 may also include radio-frequency receiver circuitry that is able to gather information on the magnitude and phase of corresponding received signals from device structures under test 14 (i.e., radio-frequency signals 28 that are reflected from device structures under test 14 and that are received using test probe 18 or radio-frequency signals 28 that have passed through at least a portion of device structures under test 14). Using the transmitted and received signals 26 and 28, the magnitude and phase of the complex impedance (sometimes referred to as a reflection coefficient) of the device structures under test may be determined.

With one suitable arrangement, test unit 20 may be a vector network analyzer (VNA), a spectrum analyzer, or other radio-frequency tester and a computer that is coupled to the test unit for gathering and processing test results. This is, however, merely illustrative. Test unit 20 may include any suitable equipment for generating radio-frequency test signals of desired frequencies while measuring and processing corresponding received signals.

By analyzing the transmitted and reflected signals, test unit 20 may obtain measurements such as S-parameter measurements that reveal information about whether device structures under test 14 are faulty. Test unit 20 may, for example, obtain an S11 (complex impedance) measurement and/or an S21 (complex forward transfer coefficient) measurement. The values of S11 and S21 (phase and magnitude) may be measured as a function of signal frequency. In situations in which device structures under test 14 are fault free, S11 and S21 measurements will have values that are relatively close to baseline measurements on fault-free structures (sometimes referred to as reference structures or a “gold” unit). In situations in which device structures under test 14 contain a fault that affects the electromagnetic properties of device structures under test 14, the S11 and S21 measurements will exceed normal tolerances. When test unit 20 determines that the S11 and/or S21 measurements have deviated from normal S11 and S21 measurements by more than predetermined limits, test unit 20 can alert an operator that device structures under test 14 likely contain a fault and/or other appropriate action can be taken.

For example, an alert message may be displayed on display 200 of test unit 20. The faulty device structures under test 14 may then be repaired to correct the fault or may be scrapped. With one suitable arrangement, an operator of test system 10 may be alerted that device structures under test 14 have passed testing by displaying an alert message such as a green screen and/or the message “pass” on display 200. The operator may be alerted that device structures under test 14 have failed testing by displaying an alert message such as a green screen and/or the message “fail” on display 200 (as examples). If desired, S11 and/or S21 data can be gathered over limited frequency ranges that are known to be sensitive to the presence or absence of faults. This may allow data to be gathered rapidly (e.g., so that the operator may be provided with a “pass” or “fail” message within less than 30 seconds, as an example).

Complex impedance measurements (S11 phase an magnitude data) on device structures under test 14 may be made by transmitting radio-frequency signals with a test probe and receiving corresponding reflected radio-frequency signals from the device under test using the same test probe. Complex forward transfer coefficient measurements (S21 phase and magnitude data) on device structures under test 14 may be made by transmitting radio-frequency signals with a first test probe and receiving a corresponding set of radio-frequency signals from device structures under test 14 using a second test probe.

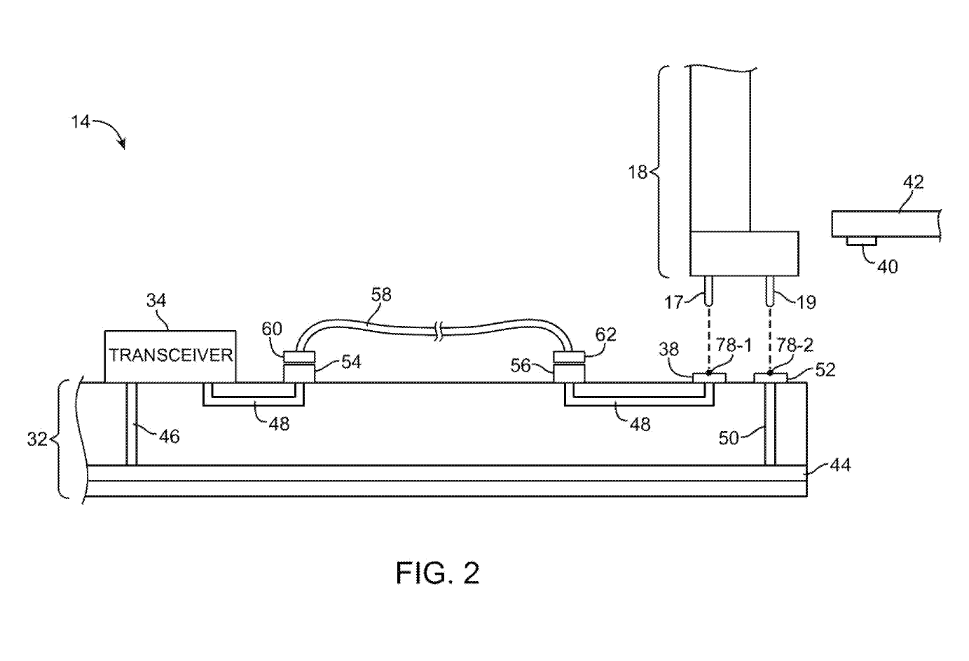

In one suitable arrangement, test system 10 may be used to test device components that are mounted on a circuit board. As shown in FIG. 2, a transceiver circuit such as transceiver 34 may be mounted on the surface of a substrate such as printed circuit board (PCB) 32. Board 32 may be a rigid printed circuit board, a flexible printed circuit board (e.g., a flex circuit), or a rigid-flex circuit. Board 32 may include at least one layer in which ground path 44 is formed. Transceiver 34 may be coupled to ground through via 46.

Transceiver 34 may be coupled to an antenna resonating element such as antenna resonating element 42 through mating conductive pads 38 and 40 (sometimes referred to as flex pads). In general, transceiver 34 may be coupled to antenna resonating element via a spring, screw, conductive foam, radio-frequency conductors, or other suitable coupling mechanisms. Antenna resonating element 42 may form part of a loop antenna, inverted-F antenna, strip antenna, planar inverted-F antenna, slot antenna, hybrid antenna that includes antenna structures of more than one type, or other suitable antennas for transmitting and receiving radio-frequency signals for a wireless electronic device. Conductive pad 38 may be formed on the surface of board 32, whereas conductive pad 40 may be mounted on antenna resonating element 42. During conducted testing, of device structures under test 14, antenna resonating element 42 may be decoupled from transceiver 34 (e.g., by unmating pads 38 and 40).

Transceiver 34 may be coupled to pad 38 via at least one transmission line path. The transmission line path through which transceiver 34 and pad 38 are electrically coupled may include conductive traces such as traces 48 formed in at least one layer in board 32, radio-frequency cable 58, and other conduits for conveying radio-frequency signals. Radio-frequency connectors 60 and 62 may be attached to first and second ends of cable 58, respectively. Cable connector 60 may be mated to a corresponding connector 54 on board 32, whereas cable connector 62 may be mated to a corresponding connector 56 on board 32.

During device assembly, cable 58 may be attached to the on-board device structures by mating connectors 60 and 62 to the corresponding on-board connectors using automated tools or manually by assembly personnel. Test probe 18 may be used to test whether cable connectors 60 and 62 are seated properly within the corresponding mating connectors. For example, pins 17 and 19 may be placed in contact with pad 38 and ground pad 52 (e.g., a conductive pad that is coupled to ground path 44 through via 50), respectively at locations 78-1 and 78-2. While test probe 18 is in this mated state, test probe 18 may be used to transmit radio-frequency test signals to device structures under test 14 and to receive corresponding signals (e.g., reflected signals and/or signals that have pass through some of structures 14). Test results gathered in this way may indicate whether or not cable 58 is properly connected between transceiver 34 and conductive pad 38.

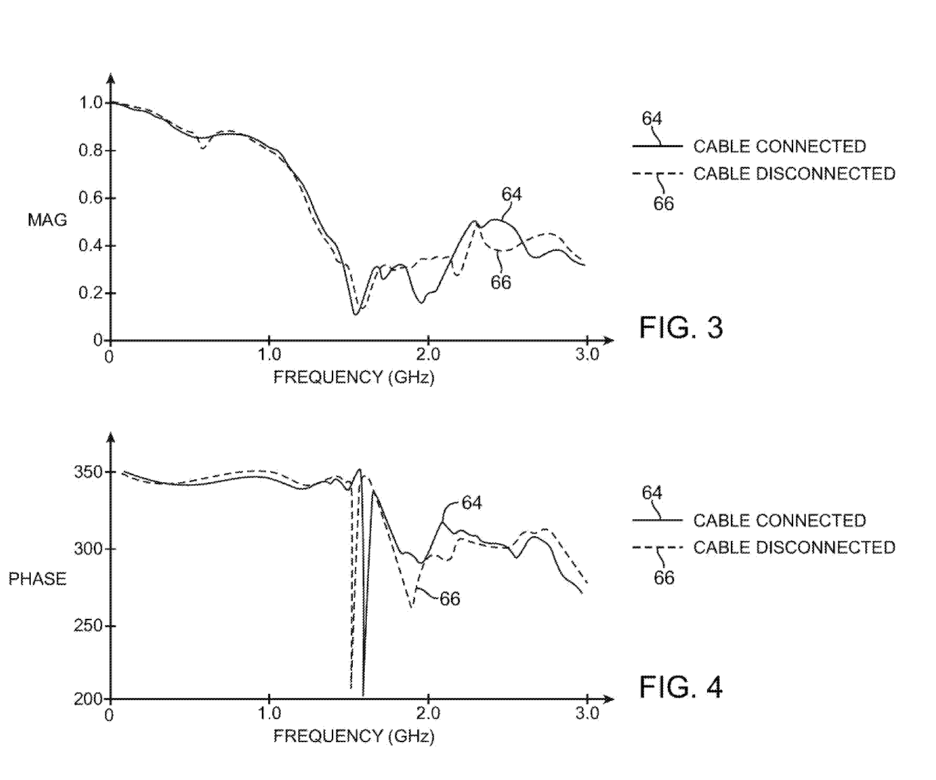

Exemplary test results gathered using test probe 18 in determining whether cable 58 is properly connected to board 32 are shown in FIGS. 3 and 4. As shown in FIGS. 3 and 4, test data gathered by tester 12 is plotted as a function of applied signal frequency over a range of signal frequencies from 0 GHz to 3 GHz. Test measurements may be made using a swept frequency from 0-3 GHz or using other suitable frequency ranges (e.g., frequency ranges starting above 0 GHz and extending to an upper frequency limit of less than 3 GHz or greater than or equal to 3 GHz). The use of a 0-3 GHz test signal frequency range in the example of FIGS. 3 and 4 is merely illustrative. In the graph of FIG. 3, the magnitude of S11 is plotted as a function of frequency. In the graph of FIG. 4, the phase of S11 is plotted as a function of frequency.

Initially, during calibration operations, test unit 20 may gather S11 measurements from device structures under test that are known to be fault free (e.g., from properly connected cables 58). When device structures under test 14 are fault free, the S11 measurements follow curves 64 of FIGS. 3 and 4 (in this example). Curves 64 may therefore represent a baseline (calibration) response for the device structures under test in the absence of faults. The baseline response serves as a reference that can be used to determine when measurements results are meeting expectations or are deviating from expectations.

If one or more faults are present, the S11 measurements made by tester 12 will deviate from curves 64 because the electromagnetic properties of structures 14 will be different than in situations in which structures 14 are free of faults. For example, an improperly-connected cable 58 will result in an impedance discontinuity in the transmission line path between transceiver 34 and pad 38. Improperly formed antenna structures such as faults in springs or screws or other metal structures (e.g., feed structures, matching element structures, resonating element structures, antenna ground structures, etc.) may also result in detectable changes in electromagnetic properties (see, e.g., curve 66 in FIGS. 3 and 4). When the test signals from test probe 18 reach structures 14, the impedance discontinuity in structures 14 (or other fault-related change in structures 14) will produce a change in received signal 28 (and the computed S11 or S21 data) that can be detected by tester 12. In the present example, the S11 measurements will follow curves 66 when the.

The discrepancy between the shape of curve 66 and the known reference response (curve 64) in FIGS. 3 and 4 is merely illustrative. Device structures under test with different configurations will typically produce different results. Provided that test results measured with tester 14 have detectable differences from the reference curves associated with satisfactory device structures under test (i.e., structures that do not contain faults such as misshapen antenna resonating element traces or other conductive structures, poorly connected or disconnected connectors, etc.), tester 12 will be able to detect when faults are present and will be able to take appropriate actions.

Actions that may be taken in response to detection of a fault in device structures under test 14 include displaying a warning (e.g., on computer monitor 200 in test unit 20 of FIG. 2), on a status light-emitting diode in test unit 20, or on other electronic equipment associated with test unit 20 that may display visual information to a user), issuing an audible alert, using positioning equipment in system 10 to automatically place the device structures under test 14 in a suitable location (e.g., a reject bin), etc.

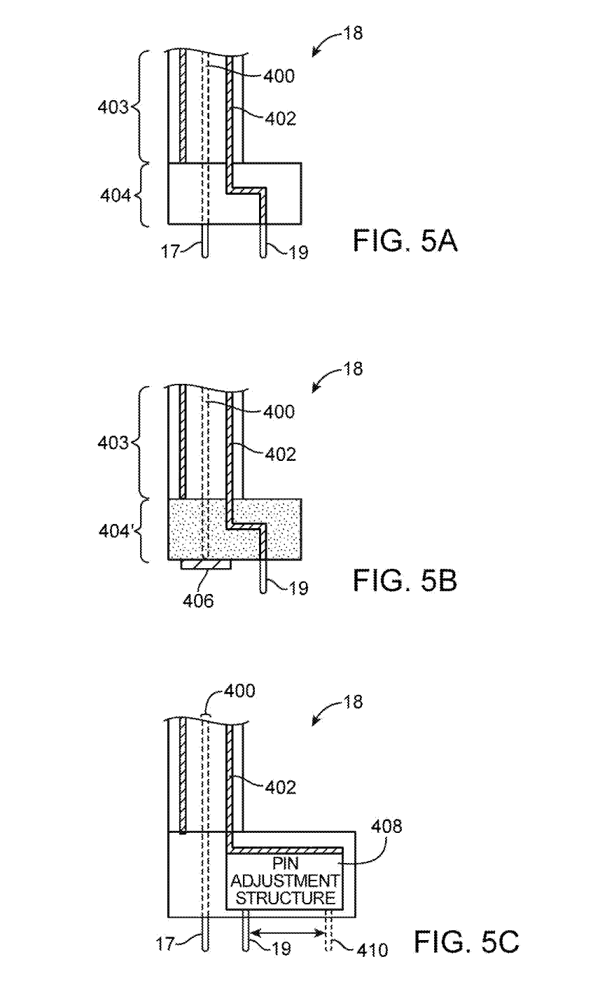

In one suitable arrangement, test probe 18 may include an inner signal conductor 400 connected to pin 17 and an outer signal conductor 402 that is connected to pin 19 (see, e.g., FIG. 5A). Conductors 400 and 402 may be separated by dielectric material, air, or other insulating material. Conductors 400 and 402 may, as an example, be held within metal probe body 403 and metal probe head 404.

In another suitable arrangement, test probe 18 may include a plastic probe housing portion such as plastic probe head 404′ attached to metal probe body 403 (see, e.g., FIG. 5B). Conductive pad 406 may be formed at a bottom surface of housing 404′. Signal conductor 400 may be placed in contact with pad 406, whereas ground conductor 402 is electrically shorted with protruding ground pin 19. Conductive pad 406 may serve as a signal pad for probe 18 may be use to provide larger surface area for contacting device structures under test 14. If desired, a ground pad may be formed on the bottom surface of housing 404′ for conductor 402.

In another suitable arrangement, test probe 18 may include a pin adjustment structure 408 within the probe housing. Pin adjustment structure 408 may allow for adjustment in the location of pin 19. For example, pin 19 may be moved from its current position to new position 410 (see, e.g., FIG. 5C). Adjustable test probe 18 configured using this arrangement may provide increased flexibility for facilitating testing of different types of device structures under test 14. For example, consider a scenario in which testing a first portion of device structures under test 14 requires that probe pins 17 and 19 be spaced at a given distance, whereas testing a second portion of device structures under test 14 requires that probe pines 17 and 19 be spaced at a distance that is different than the given distance. In this example, a single test probe 18 having adjustment structure 408 may be used to support testing of the first and second portions of structures 14 instead of using two separate test probes that have pins at fixed positions. The embodiments of FIGS. 5B and 5C may be used in combination to provide a test probe having a conductive contact pad and an adjustable probe pin, if desired.

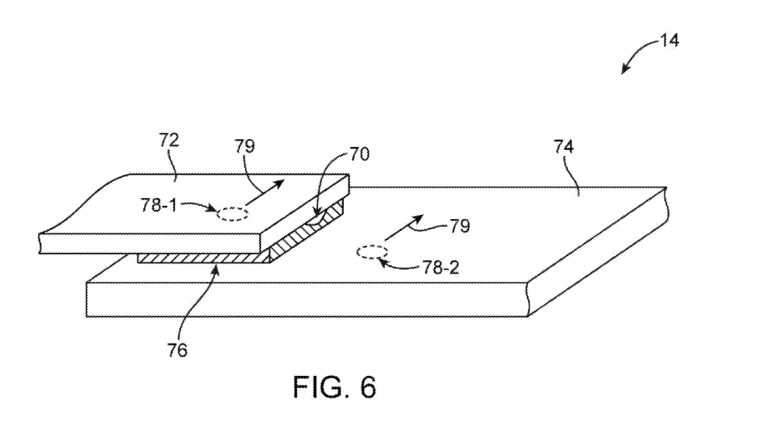

FIG. 6 is a perspective view of illustrative device structures under test 14 that includes a first conductive member 72 attached to a second conductive member 74 via conductive foam 76. Proper coupling between the first and second conductive member 72 and 74 may require that conductive foam 76 be uniform in thickness to provide sufficient conductivity. Due to error in manufacturing device structures 14, conductive foam 76 may have a non-uniform portion 70 (i.e., an air bubble, missing piece of foam, or other non-conductive material wedged between members 72 and 74).

During test set-up operations, calibration measurements may be made on members 72 and 74 connected via a uniform conductive foam layer. Test 12 may then be used to make S11 and/or S21 measurements on partially assembled devices having conductive members 72 and 74 during production testing. A computer or other computing equipment in test 12 may be used to compare the expected signature of structures 14 to the measured data (e.g., S11 and/or S21 in magnitude, phase, or both magnitude and phase). If differences are detected, an operator may be instructed to rework or scrap structures 14 or other suitable actions may be taken. As shown in FIG. 6, test probe 18 may be used to make contact with members 72 and 74 at respective locations 78-1 and 78-2 when gathering test results. If desired, the position of test probe 18 may be moved in direction 79 to detect the location of defective portion 70.

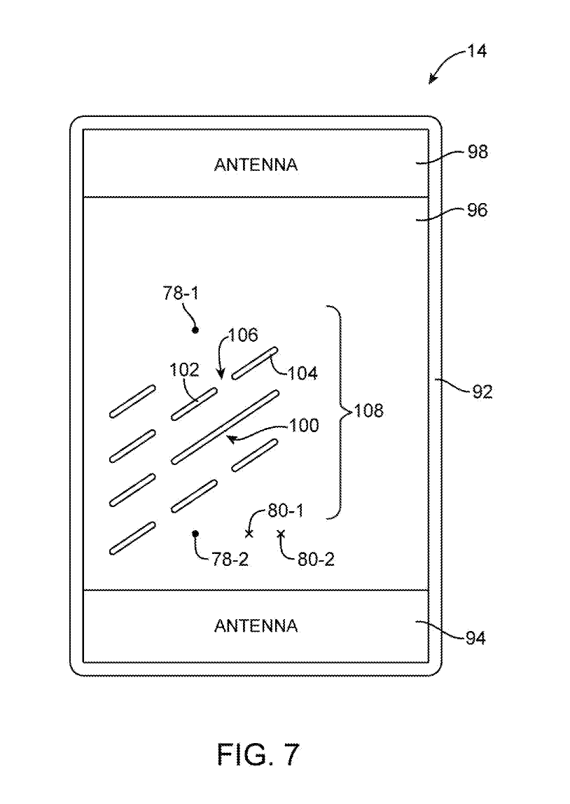

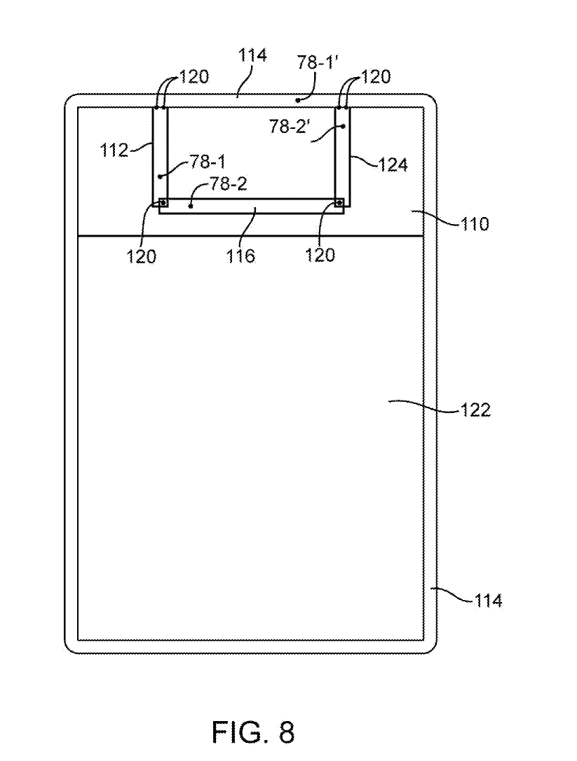

If desired, test system 10 may be used to test device structures such as electronic device housing structures. FIG. 7 is a top view of illustrative electronic device housing structures of the type that may be tested using test system 10. As shown in FIG. 7, device structures under test 14 may include a partly formed electronic device (e.g., a cellular telephone, media player, computer, etc.) having a peripheral conductive housing member such as peripheral conductive housing member 92 and a planar conductive housing member such as planar conductive housing member 96. Antennas 94 and 98 may be located at opposing ends of structures 14 (as an example). Planar conductive housing member 96 may be formed from one or more sheet metal members that are connected to each other by over-molded plastic and/or welds or other fastening mechanism. Planar conductive housing member 96 may be welded to the left and right sides of planar conductive housing member 92.

Conductive housing members in device structures under test 14 may have structural features such as openings (e.g., air-filled or plastic-filled openings or other dielectric-filled openings that are used in reducing undesirable eddy currents produced by antenna 94 and/or antenna 98), peripheral shapes, three-dimensional shapes, and other structural features whose electromagnetic properties is altered when a fault is present due to faulty manufacturing and/or assembly operations. For example, conductive housing member 96 may have openings such as openings 108. Openings 108 normally may have relatively short slots such a slots 102 and 104 that are separated by intervening portions of member 96, such as portions 106. Due to an error in manufacturing member 96, portions 106 may be absent. If desired, openings such as meshes of holes, grooves, or openings of any shape may be formed in member 96.

In the example of FIG. 7, portions 106 are absent between a pair of slots, so the slots merged to form relatively long slot 100. During test set-up operations, calibration measurements may be made on a properly fabricated version of member 96 (i.e., a version of member 96 where slot 100 is divided into two openings). Tester 12 may then be used to make S11 and/or S21 measurements. A computer or other computing equipment in tester 12 may be used to compare the expected signature of device structures under test 14 to the measured data (e.g., S11 and/or S21 in magnitude, phase, or both magnitude and phase). If differences are detected, an operator may be instructed to rework or scrap structures 14 or other suitable actions may be taken. As shown in FIG. 7, test probe 18 may be used to make contact with member 96 at locations 78-1 and 78-2 when gathering test results so that test signals can pass through the region in which openings 108 are formed.

FIG. 8 is a top view of illustrative device structures under test 14 that include welds 120. In the example of FIG. 8, structures 14 may correspond to a partly assembled electronic device such as a partly assembled cellular telephone, computer, or media player (as examples). Structures 14 may include peripheral conductive housing member 114 and conductive planar housing member 122. Member 122 may be separated from peripheral conductive housing member by dielectric-filled gap (opening) 110. Conductive structures such as members 112, 116, and 124 may be connected to each other by welds 120.

When welds 120 are formed properly, tester 12 will make S11 measurements (or S21 measurements) that match calibration results for properly welded structures. When welds 120 contain faults (e.g., one or more missing or incomplete welds or a broken weld), the test measurements may exhibit detectable changes relative to the calibration results. When such a change is detected, appropriate actions may be taken. For example, an operator may be alerted so that structures 14 may be reworked, inspected further using different testing equipment, or scrapped. As shown in FIG. 8, test probe 18 may be used to make contact with members 112 and 116 at respective locations 78-1 and 78-2 (to detect whether members 112 and 116 are properly welded together). As another example, test probe 18 may also be used to make contact with members 124 and housing member 114 at respective locations 78-1′ and 78-2′ (to detect whether members 124 and 114 are properly welded together).

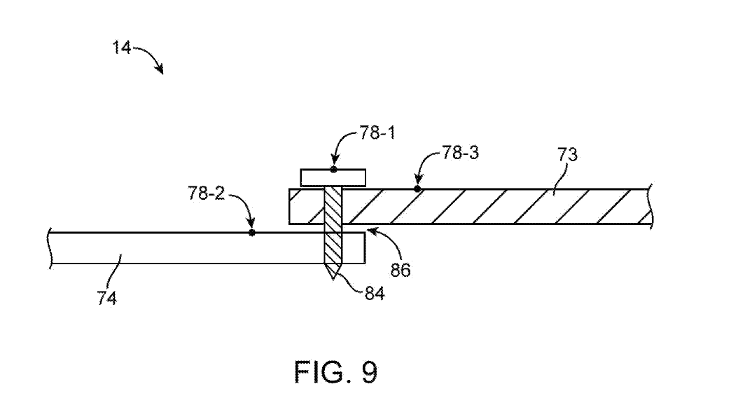

FIG. 9 is a side view of illustrative device structures under test 14 that includes a non-conductive member 73 attached to conductive member 74 using a screw 84. Due to errors during assembly, screw 84 may be partially screwed in to reveal undesirable gap 86 between members 73 and 74, screw 84 may be cracked, screw 84 may be cross-threaded, etc.

During test set-up operations, calibration measurements may be made on structures 14 having properly secured screw 84. Test 12 may then be used to make S11 and/or S21 measurements on partially assembled devices having members 73 and 74 during production testing. A computer or other computing equipment in test 12 may be used to compare the expected signature of structures 14 to the measured data (e.g., S11 and/or S21 in magnitude, phase, or both magnitude and phase). If differences are detected, an operator may be instructed to rework or scrap structures 14 or other suitable actions may be taken. As shown in FIG. 9, test probe 18 may be used to make contact with screw 84 and member 74 at respective locations 78-1 and 78-2 when gathering test results to allow test signals to pass through screw 84 and conductive member 78-2. If desired, test probe 18 may also be used to make contact with members 73 and 74 at respective locations 78-3 and 78-2 when gathering test results to allow test signals to pass between points 78-3 and 78-2.

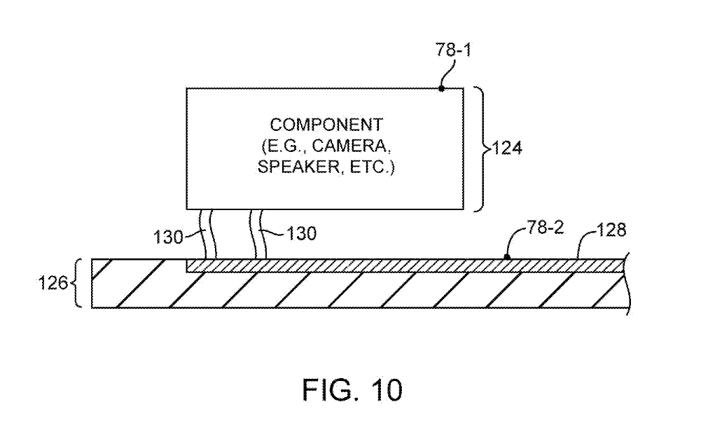

Device structures under test 14 may include components such as speakers, microphones, switches, buttons, connectors, printed circuit boards, cables, light-emitting devices, sensors, displays, cameras, and other components. These components may be attached to each other using springs and other electrical connection mechanisms. As shown in the illustrative arrangement of FIG. 10, a component such as component 124 (e.g., a speaker, microphone, camera, etc.) may be coupled to at least one conductive trace 128 formed on the surface of printed circuit board substrate 126 using one, two, or more than two springs 130 or other conductive coupling mechanisms. If component 124 and board 126 are not assembled correctly, springs 130 may not make satisfactory electrical contact to trace 128.

Tester 12 may detect this change by using test probe 18 to make contact with component 124 and trace 128 at respective locations 78-1 and 78-2 and comparing the test measurements to calibration measurements on known properly assembled structures. If the test measurements differ from the expected measurements, appropriate actions may be taken. For example, an operator may be alerted so that structures 14 may be reworked, inspected further using different testing equipment, or scrapped.

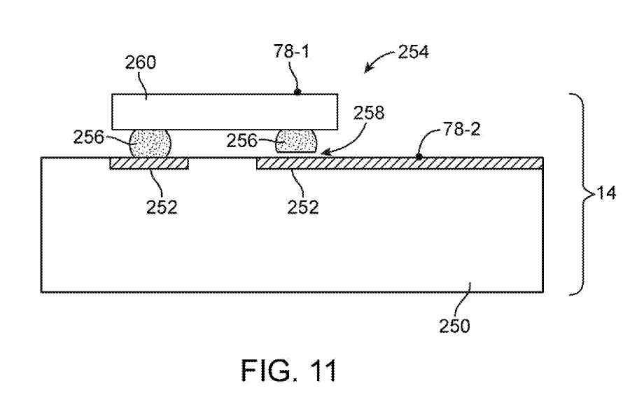

FIG. 11 is a side view of an illustrative electronic component such as surface mount assembly (SMA) structures 254 mounted to a substrate such as substrate 250 (e.g., a printed circuit board). This type of electronic device structure may be tested using test probe 18 and system 12 (e.g., by contacting structures 254 and trace 252 at respective locations 78-1 and 78-2). When properly assembled, electronic component 260 will be attached to traces 252 on substrate 250 using solder balls 256. In the presence of a fault such as gap 258, the radio-frequency signature of device structures under test 14 will be different, which can be detected by system 12 (e.g., using S11 and/or S21 measurements).

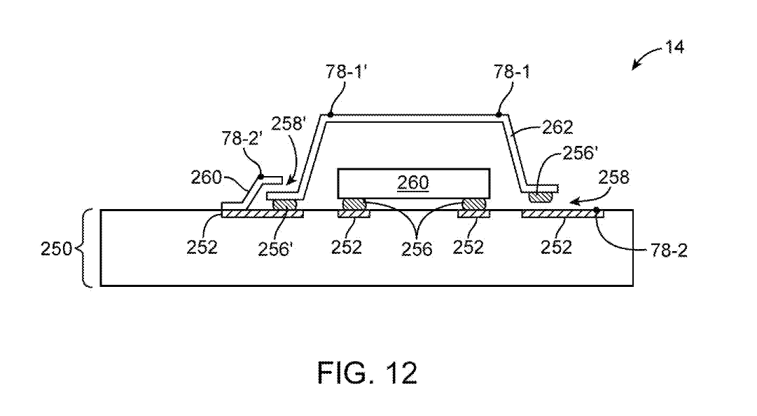

In the example of FIG. 12, an electronic device component such as component 260 has been electromagnetically shielded using electromagnetic shielding can 262. When properly assembled, springs such as spring 260 and/or solder such solder 256′ may form electrical connections between can 262 and traces such as 252 (e.g., ground traces) on substrate 250. In the presence of a fault such as an incomplete solder connection (shown as gap 258) or an incomplete spring connection (shown as gap 258′), system 12 can detect abnormal S11 and/or S21 characteristics. Incomplete solder connection 258 may be detected using test probe 18 to contact shield can 262 and trace 252 at respective locations 78-1 and 78-2, whereas incomplete spring connection 258′ may be detected using test probe 18 to contact shield can 262 and spring 260 at respective locations 78-1′ and 78-2′ (as examples).

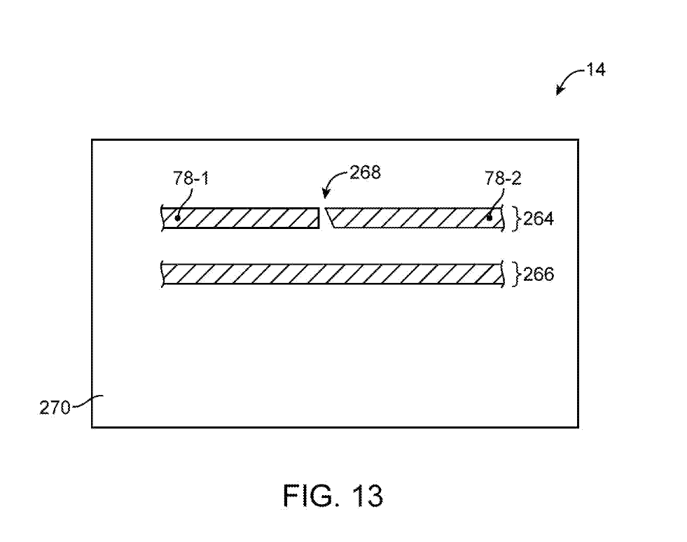

As shown in FIG. 13, device structures under test 14 may include traces such as traces 264 and 266 on substrate 270. Traces 262 and 264 may, for example, be part of a patterned metal layer that forms part of a transmission line or a digital bus or other signal path that interconnects electronic components within an electronic device. During testing to gather S11 and/or S21 measurements, probe 18 may be used to contact opposing ends of a trace such as trace 264 at locations 78-1 and 78-2 to detect the presence of faults such as shorts, opens, etc. In the example of FIG. 18, trace 264 contains an open fault due to the presence of gap 268.

Tester 12 may, in general, be used to test electronic device structures that include antennas, conductive structures such as conductive housing structures, connectors, springs, and other conductive structures that form electrical connections, speakers, shielding cans, solder-mounted components such as integrated circuits, transmission lines and other traces, layers of conductive foam, other electrical components, or any other suitable conductive structures that interact with transmitted radio-frequency electromagnetic signals. The foregoing examples are merely illustrative.

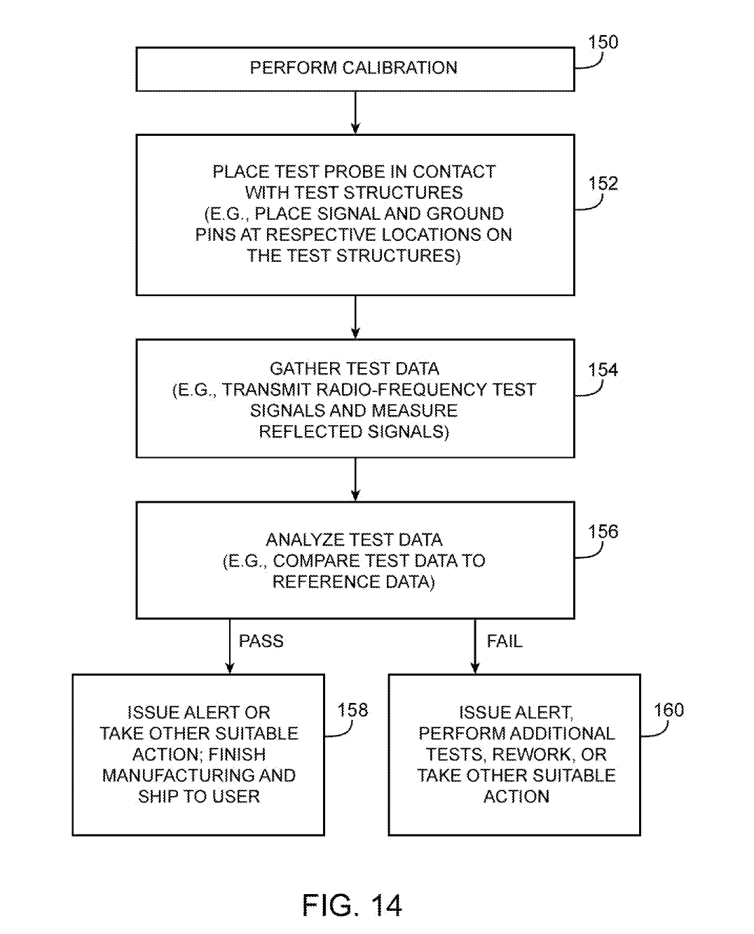

Illustrative steps involved in performing contact tests on device structures under test 14 using tester 12 of system 10 are shown in FIG. 14.

At step 150, calibration operations may be performed on properly manufactured and assembled device structures. In particular, tester 12 may use contact test probe 18 to transmit and receive radio-frequency signals in a desired frequency range (e.g., from 0 Hz to 3 GHz, from 3-14 GHz, a subset of one of these frequency ranges, or another suitable frequency range). Signals corresponding to the transmitted signals may be received from the device structures under test and processed with the transmitted signals to obtain S11 and/or S21 measurements or other suitable test data. The S11 and/or S21 measurements or other test measurements that are made on the properly manufactured and assembled device structures may be stored in storage in tester 12 (e.g., in storage on a vector network analyzer, in storage on computing equipment such as a computer or network of computers in test unit 20 that are associated with the vector network analyzer, etc.).

If desired, the device structures that are tested during the calibration operations of step 150 may be “limit samples” (i.e., structures that have parameters on the edge or limit of the characteristic being tested). Device structures of this type are marginally acceptable and can therefore be used in establishing limits on acceptable device performance during calibration operations.

At step 152, the signal and ground pins in test probe 18 may be placed in contact at desired locations on device structures under test 14 (e.g., manually or using computer-controlled positioners such as positioner 16 of FIG. 1).

At step 154, tester 12 may use test probe 18 to gather test data. During the operations of step 154, tester 12 may use test probe 18 to transmit and receive radio-frequency signals in a desired frequency range (e.g., from 0 Hz to 3 GHz, 3 GHz to 14 GHz, or other suitable frequency range, preferably matching the frequency range used in obtaining the calibration measurements of step 150). Conducted test data such as S11 and/or S21 measurements or other suitable test data may be gathered. The S11 and/or S21 measurements (phase and magnitude measurements for impedance and forward transfer coefficient) may be stored in storage in tester 12.

At step 156, the radio-frequency test data may be analyzed. For example, the test data that was gathered during the operations of step 154 may be compared to the baseline (calibration) data obtained during the operations of step 150 (e.g., by calculating the difference between these sets of data and determining whether the calculated difference exceeds predetermined threshold amounts, by comparing test data to calibration data from limit samples that represents limits on acceptable device structure performance, or by otherwise determining whether the test data deviates by more than a desired amount from acceptable data values). After computing the difference between the test data and the calibration data at one or more frequencies to determine whether the difference exceeds predetermined threshold values, appropriate actions may be taken.

For example, if the test data and the calibration data differ by more than a predetermined amount, tester 12 may conclude that device structures under test 14 contain a fault and appropriate actions may be taken at step 160 (e.g., by issuing an alert, by informing an operator that additional testing is required, by displaying information instructing an operator to rework or scrap the device structures, etc.). If desired, visible messages may be displayed for an operator of system 12 at step 160 using display 200. In response to a determination that the test data and the calibration data differ by less than the predetermined amount, tester 12 may conclude that device structures under test 14 have been manufactured and assembled properly and appropriate actions may be taken at step 158 (e.g., by issuing an alert that the structures have passed testing, by completing the assembly of the structures to form a finished electronic device, by shipping the final assembled electronic device to a customer, etc.). If desired, visible messages may be displayed for an operator of system 12 at step 158 using display 200.

The foregoing is merely illustrative of the principles of this invention and various modifications can be made by those skilled in the art without departing from the scope and spirit of the invention. The foregoing embodiments may be implemented individually or in any combination.

What is claimed is:

1. A method for testing device structures under test using a test probe, wherein the device structures under test includes a first conductive structure coupled to a second conductive structure, the method comprising:
placing the test probe in contact with the first and second conductive structures;
transmitting radio-frequency test signals to the device structures under test using the test probe;
receiving corresponding radio-frequency test signals from the device structures under test using the test probe; and
determining from at least the received radio-frequency test signals whether the first and second conductive structures are properly coupled.

2. The method defined in claim 1 wherein the test probe includes first and second contact pins, and wherein placing the test probe in contact with the first and second conductive structures comprises placing the first and second contact pins in contact with the first and second conductive structures, respectively.

3. The method defined in claim 1 wherein determining from at least the received radio-frequency test signals whether the first and second conductive structures are properly coupled comprises using reflected radio-frequency test signals to determine whether the first and second conductive structures are properly coupled.

4. The method defined in claim 3 wherein determining from at least the reflected radio-frequency test signals whether the first and second conductive structures are properly coupled comprises comparing measured data for the device structures under test to calibration data.

5. The method defined in claim 2 wherein the first and second conductive structures comprise first and second radio-frequency connectors, and wherein determining from at least the received radio-frequency test signals whether the first and second conductive structures are properly coupled comprises determining whether the first and second radio-frequency connectors are properly connected to each other.

6. The method defined in claim 2 wherein the first conductive structure comprises an electronic component with springs and wherein determining from at least the received radio-frequency test signals whether the first and second conductive structures are properly coupled comprises determining whether the springs and second conductive structure are properly connected to each other.

7. The method defined in claim 2 wherein determining from at least the received radio-frequency test signals whether the first and second conductive structures are properly coupled comprises determining whether the first and second conductive structures are properly welded to each other.

8. The method defined in claim 2 wherein determining from at least the received radio-frequency test signals whether the first and second conductive structures are properly coupled comprises determining whether the first and second conductive structures are properly soldered to each other.

9. The method defined in claim 2 wherein the first conductive structure comprises an electromagnetic shield structure and wherein determining from at least the received radio-frequency test signals whether the first and second conductive structures are properly coupled comprises determining whether the electromagnetic shield structure and the second conductive structure are properly electrically connected to each other.

10. The method defined in claim 2 wherein the first and second conductive structures are coupled via a conductive foam layer and wherein determining from at least the received radio-frequency test signals whether the first and second conductive structures are properly coupled comprises determining whether the conductive foam layer contains a fault.

11. The method defined in claim 2 wherein the first conductive structure comprises a screw and wherein determining from at least the received radio-frequency test signals whether the first and second conductive structures are properly coupled comprises determining whether the screw is properly secured to the second conductive structure.

12. A method for testing device structures under test using a test probe, wherein the device structures under test includes a conductive housing structure having at least one opening, the method comprising:
placing the test probe in contact with the conductive housing structure;
transmitting radio-frequency test signals to the device structures under test using the test probe;
receiving corresponding radio-frequency test signals from the device structures under test using the test probe; and
determining from at least the received radio-frequency test signals whether the opening in the conductive housing structure is properly formed.

13. The method defined in claim 12, wherein the conductive housing structure comprises an antenna grounding structure having at least one opening and wherein the placing the test probe in contact with the conductive housing structure comprises placing first and second contact pins of the test probe in contact with the antenna grounding structure at opposing sides of the at least one opening.

14. The method defined in claim 12 wherein determining from at least the received radio-frequency test signals whether the opening in the conductive housing structure is properly formed comprises using reflected radio-frequency test signals to determine whether the opening in the conductive housing structure is properly formed.

15. The method defined in claim 12 wherein determining from at least the reflected radio-frequency test signals whether the opening in the conductive housing structure is properly formed comprises comparing measured data for the device structures under test to calibration data.

16. A method of testing device structures under test with test equipment that includes a radio-frequency test probe, wherein the device structures under test include a transmission line path, transceiver circuitry coupled to a first end of the transmission line path, and an antenna resonating element removably coupled to a second end of the transmission line path through a coupling member, the method comprising:
with the radio-frequency test probe, gathering radio-frequency test measurements through the coupling member while the antenna resonating element is removed from the coupling member; and
determining from at least the gathered radio-frequency test measurements whether the device structures under test contain a fault.

17. The method defined in claim 16, wherein the test probe includes a signal pin and at least one ground pin, the method further comprising placing the signal pin in contact with the coupling member and the at least one ground pin in contact with a corresponding ground pad coupled to the transmission line path while gathering the radio-frequency test measurements.

18. The method defined in claim 16, wherein the transmission line path includes at least a radio-frequency cable and wherein determining whether the device structures under test contain a fault comprises determining whether the radio-frequency cable is properly connected between the transceiver circuitry and the coupling member.

19. The method defined in claim 16, wherein the coupling member comprises a conductive member selected from the group consisting of: a conductive pad, spring, screw, radio-frequency connector, and shorting pin.

20. A radio-frequency test probe comprising:
a signal conductor;
at least one ground conductor;
a probe body through which the signal conductor and the at least one ground conductor are formed; and
a nonconductive member that is attached to the probe body and that includes at least one conductive pad formed on its surface, wherein at least one of the signal and ground conductors is coupled to the conductive pad.

21. The radio-frequency test probe defined in claim 20, wherein the nonconductive member is formed from dielectric material.

22. The radio-frequency test probe defined in claim 20, further comprising an adjustment structure configured to adjust a distance between the signal and ground conductors in the test probe.

23. The radio-frequency test probe defined in claim 20, wherein at least one of the signal and ground conductors is coupled to a spring-loaded pin.
